(19) United States
(12) Patent Application Publication
(10) Pub. No.: US 2025/0142987 A1
(43) Pub. Date: May 1, 2025

(54) OPTICAL SENSING APPARATUS

(71) Applicant: ARTILUX, INC., MENLO PARK, CA (US)

(72) Inventors: Yun-Chung Na, San Jose, CA (US); You-Ru Lin, HSINCHU COUNTY (TW); Tsung-Ting Wu, HSINCHU COUNTY (TW); Yu-Hsuan Liu, HSINCHU COUNTY (TW)

(21) Appl. No.: 18/819,123

(22) Filed: Aug. 29, 2024

Related U.S. Application Data
(60) Provisional application No. 63/594,424, filed on Oct. 31, 2023.
(60) Provisional application No. 63/597,339, filed on Nov. 9, 2023.
(60) Provisional application No. 63/555,898, filed on Feb. 21, 2024.

(51) Int. Cl. H01L 27/146; G01J 3/28; H01L 31/0352

(52) U.S. Cl. CPC H10F 39/1847; G01J 3/2803; H10F 39/1843; H10F 77/1468; G01J 2003/2813

(57) ABSTRACT

Methods, devices, and systems for optical sensing are provided. In one aspect, an optical sensing apparatus includes: a first absorption region configured to absorb light in at least a first spectrum with visible or near infrared wavelengths; a second absorption region formed over the first absorption region, the second absorption region configured to absorb light in at least a second spectrum with near infrared or shortwave infrared wavelengths; and a third absorption region formed over the second absorption region, the third absorption region configured to absorb light in at least a third spectrum with shortwave infrared or mid-wave infrared wavelengths.

### CROSS-REFERENCE TO RELATED APPLICATION

This application claims the benefit of U.S. Provisional Patent Application No. 63/594,424, filed Oct. 31, 2023, U.S. Provisional Patent Application No. 63/597,339, filed Nov. 9, 2023, and U.S. Provisional Patent Application No. 63/555,898, filed Feb. 21, 2024, which are incorporated by reference herein in their entireties.

### TECHNICAL FIELD

This disclosure relates to sensors, and more particularly, to optical sensors.

### BACKGROUND

Sensors are being used in many applications, such as smartphones, robotics, autonomous vehicles, proximity sensing, biometric sensing, image sensors, high-speed optical receiver, data communications, direct/indirect time-of-flight (TOF) ranging or imaging sensors, medical devices, etc. for object recognition, image enhancement, material recognition, and other relevant applications.

### SUMMARY

The present disclosure describes systems, devices, methods, and techniques for optical sensing.

One aspect of the present disclosure features an optical sensing apparatus including: a first absorption region configured to absorb light in at least a first spectrum at visible or near infrared wavelengths; a second absorption region formed over the first absorption region, the second absorption region configured to absorb light in at least a second spectrum at near infrared or shortwave infrared wavelengths; and a third absorption region formed over the second absorption region, the third absorption region configured to absorb light in at least a third spectrum at shortwave infrared or mid-wave infrared wavelengths.

In some implementations, the first absorption region includes silicon, and where the second absorption region includes germanium.

In some implementations, the third absorption region includes multiple strain-balanced layers of germanium-silicon compounds and germanium-tin compounds.

In some implementations, the third absorption region includes a layer of germanium-tin compounds.

In some implementations, the optical sensing apparatus further includes a first substrate.

In some implementations, at least the second absorption region and the third absorption region are partially embedded or fully embedded in the first substrate.

In some implementations, at least the second absorption region and the third absorption region are formed over the first substrate.

In some implementations, the optical sensing apparatus further includes an optical structure, where the first substrate is arranged between the optical structure and the first absorption region.

In some implementations, the optical structure includes a metalens or a curved lens.

In some implementations, the optical structure includes an optical wavelength filter.

In some implementations, the optical sensing apparatus further includes a second substrate that includes circuitry configured to collect electric carriers generated by the first absorption region, the second absorption region, or the third absorption region.

In some implementations, the first substrate is directly or flipped bonded to the second substrate.

In some implementations, the first substrate is discrete from the second substrate.

In some implementations, the optical sensing apparatus further includes a first buffer layer formed between the second absorption region and the third absorption region.

In some implementations, the optical sensing apparatus further includes a first carrier-collection layer configured to collect and to output free-carriers of a first polarity, and a second carrier-collection layer configured to collect and to output free-carriers of a second polarity.

In some implementations, the second carrier-collection layer is coupled to a first control voltage, where the second photo-detecting region is coupled to a second control voltage, and where the first carrier-collection layer is coupled to a third control voltage.

In some implementations, during an operation of the optical sensing apparatus, the first control voltage operates under a lower voltage value than the second control voltage, and the second control voltage operates under a lower voltage value than the third control voltage, such that photo-carriers generated by the first absorption region, the second absorption region, and the third absorption region are collected by the first carrier-collection layer.

In some implementations, during an operation of the optical sensing apparatus, the first control voltage operates under an equal or higher voltage value than the second control voltage, and the second control voltage operates under a lower voltage value than the third control voltage, such that photo-carriers generated by the third absorption region are not collected by the first carrier-collection layer.

In some implementations, the optical sensing apparatus further includes an interface dopant layer formed between the first absorption region and the second first absorption region.

In some implementations, during an operation of the optical sensing apparatus, the second control voltage and the third control voltage are applied to create a carrier multiplication region in the first absorption region.

In some implementations, the optical sensing apparatus is configured to operate under a Geiger mode.

In some implementations, the optical sensing apparatus further includes a second buffer layer formed between the interface dopant layer and the second first absorption region.

In some implementations, the second absorption region is embedded in a trench of a substrate.

Another aspect of the present disclosure features an optical sensing apparatus including a plurality of sensing areas. Each sensing area includes: a first absorption region configured to absorb light in at least a first spectrum at visible or near infrared wavelengths; a second absorption region formed over the first absorption region, the second absorption region configured to absorb light in at least a second spectrum at near infrared or shortwave infrared wavelengths; and a third absorption region formed over the second absorption region, the third absorption region configured to absorb light in at least a third spectrum at shortwave infrared or mid-wave infrared wavelengths.

In some implementations, the optical sensing apparatus further includes a plurality of optical structures formed over the plurality of sensing areas.

In some implementations, the plurality of optical structures include optical wavelength filters configured to pass multiple different wavelength ranges of light to respective sensing areas of the plurality of sensing areas.

In some implementations, the optical sensing apparatus further includes readout circuitry configured to output electrical signals generated by absorbed optical signals.

In some implementations, the optical sensing apparatus further includes processing circuitry configured to process the electrical signals to determine one or more of blood oxygen (biomolecule) information, alcohol (molecule) information, material information, glucose information, ambient light information, or proximity information associated with an object sensed by the optical sensing apparatus.

Another aspect of the present disclosure features a method of forming an optical sensing apparatus, including: forming a first absorption region configured to absorb light in at least a first spectrum at visible or near infrared wavelengths; forming a second absorption region formed over the first absorption region, the second absorption region configured to absorb light in at least a second spectrum at near infrared or shortwave infrared wavelengths; and forming a third absorption region formed over the second absorption region, the third absorption region configured to absorb light in at least a third spectrum at shortwave infrared or mid-wave infrared wavelengths.

Another aspect of the present disclosure features an optical sensing apparatus including: a n-doped silicon layer; a silicon layer formed over the n-doped silicon layer; a p-doped silicon layer formed over the silicon layer; a first p-doped germanium layer formed over the p-doped silicon layer; a superlattice structure formed over the p-doped germanium layer, the superlattice structure including multiple alternating Ge₁₋ₓSnₓ and Ge_{1-y}Si_{y} layers, where x and y is between 0 and 1; and a second p-doped germanium layer formed over the superlattice structure.

In some implementations, the optical sensing apparatus further includes a first buffer layer formed between the first p-doped germanium layer and the superlattice structure.

In some implementations, the optical sensing apparatus further includes a second buffer layer formed between the p-doped silicon layer and the first p-doped germanium layer.

In some implementations, the second p-doped germanium layer is coupled to a first control voltage, where the first p-doped germanium layer is coupled to a second control voltage, and where the n-doped silicon layer is coupled to a third control voltage.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

The foregoing aspects and many of the advantages of this application will become more readily appreciated as the same becomes better understood by reference to the following detailed description, when taken in conjunction with the accompanying drawings:

FIG. 1A-1D illustrate cross-sectional views of example photodetectors.

FIG. 2A-2C illustrate cross-sectional views of example photodetectors.

FIGS. 3A and 3B illustrate cross-sectional views of example photodetectors.

FIG. 4A illustrates a cross-sectional view of an example photodetector.

FIG. 4B illustrates a top view of an example photodetector.

FIG. 5A illustrates a cross-sectional view of an example photodetector.

FIG. 5B illustrates a top view of an example photodetector.

FIG. 6 illustrates an example sensing system.

FIG. 7A-7B illustrate cross-sectional views of example photodetectors.

Like reference numbers and designations in the various drawings indicate like elements.

### DETAILED DESCRIPTION

As used herein, the terms such as “first”, “second”, “third”, “fourth” and “fifth” describe various elements, components, regions, layers and/or sections, these elements, components, regions, layers and/or sections should not be limited by these terms. These terms may be only used to distinguish one element, component, region, layer or section from another. The terms such as “first”, “second”, “third”, “fourth” and “fifth” when used herein do not imply a sequence or order unless clearly indicated by the context. The terms “photo-detecting”, “photo-sensing”, “light-detecting”, “light-sensing” and any other similar terms can be used interchangeably.

Spatial descriptions, such as “above”, “over,”, “under”, “top”, and “bottom” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the term “intrinsic” means that the semiconductor material is without intentionally adding dopants. As used herein, the terms “photodetector”, “optical sensor”, “optical sensing apparatus”, or other similar terms can include a device that has been designed and/or operated as a photodiode (PD), an avalanche photodiode (APD), a single-photon avalanche diode (SPAD), or a locked-in PD.

Hyperspectral detection is used in remote sensing and imaging to capture and analyze a wide range of wavelengths within the electromagnetic spectrum. Unlike standard color or multispectral imaging, hyperspectral sensors capture data at numerous narrow, contiguous spectral bands. This provides highly detailed information about the spectral characteristics of objects or materials in the scene. Hyperspectral detection can be used in applications such as bio-signal detection (e.g., blood oxygen, glucose, etc.), alcohol detection, ambient light or proximity detection, environmental monitoring (e.g., identifying pollutants), or mineral exploration, etc. Using silicon-based sensors in hyperspectral detection can be desirable due to its cost-effective and CMOS integration-compatibility advantages. However, silicon-based sensors are not suitable for all hyperspectral applications, especially those requiring coverage in other spectral regions, such as the shortwave infrared (SWIR) region. A silicon-based sensor that can detect visible, NIR, and SWIR spectral regions would therefore be advantageous.

Implementations of the present disclosure provide sensors, and more particularly, to optical sensors that detects light in the visible (e.g., wavelength range from 380 nm to 780 nm, or any similar wavelength range as defined by a particular application), the near-infrared (NIR, e.g., wavelength range from 780 nm to 1000 nm, or any similar wavelength range as defined by a particular application), the shortwave infrared (SWIR, e.g., wavelength range from 1000 nm to 3000 nm, or any similar wavelength range as defined by a particular application), and/or the mid-wave infrared (MIR, e.g., wavelength range from 3000 nm to 5000 nm, or any similar wavelength range as defined by a particular application). As a technical advantage, the photodetector described herein may detect light spanning over a wide spectrum (e.g., from visible to MIR spectrum).

Sensors implemented in the present disclosure can be used in many applications, such as smartphones, robotics, autonomous vehicles, proximity sensing, biometric sensing, image sensors, high-speed optical receiver, data communications, direct/indirect time-of-flight (TOF) ranging or imaging sensors, medical devices, etc. for object recognition, image enhancement, material recognition, and other relevant applications.

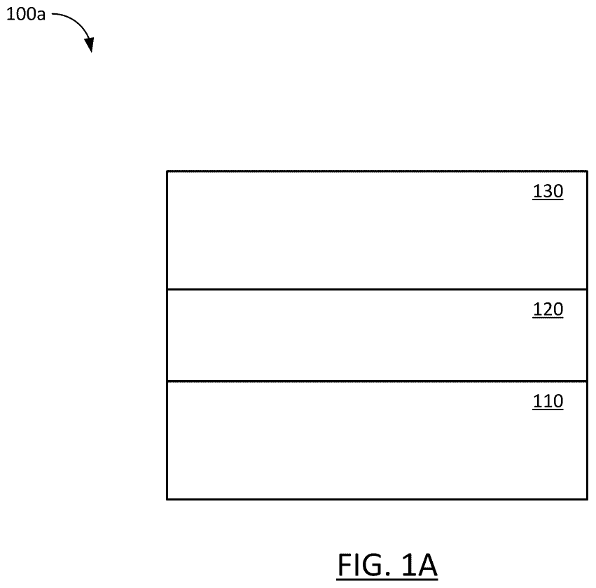

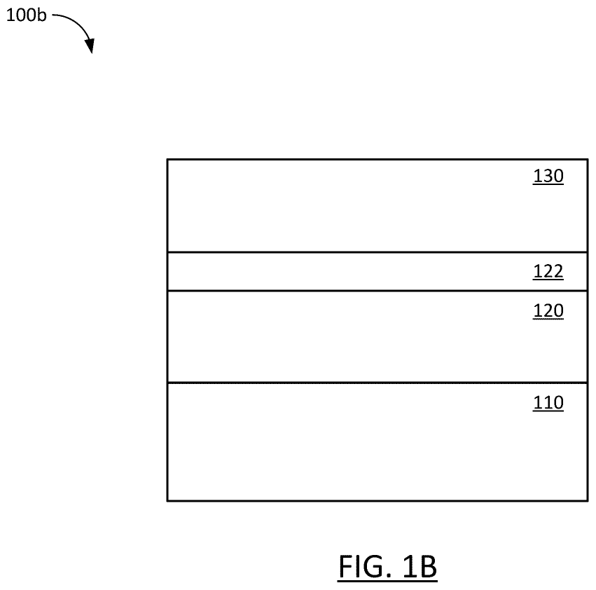

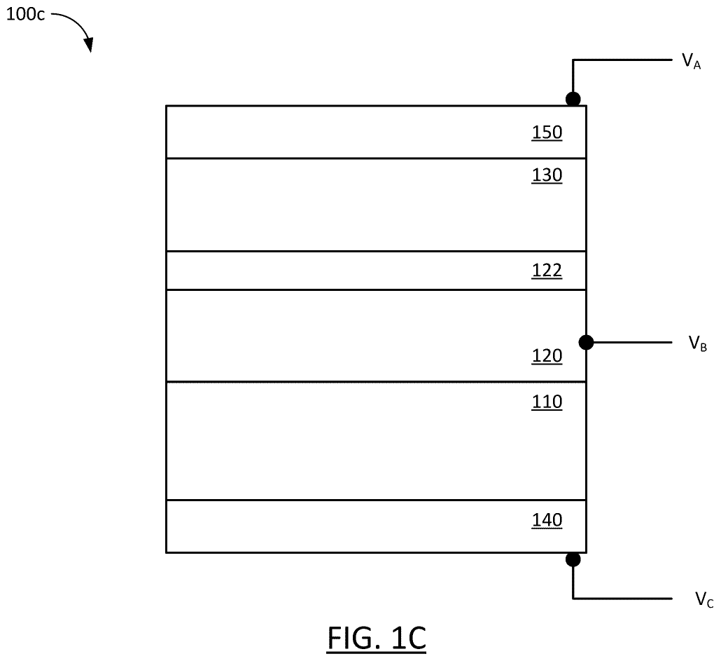

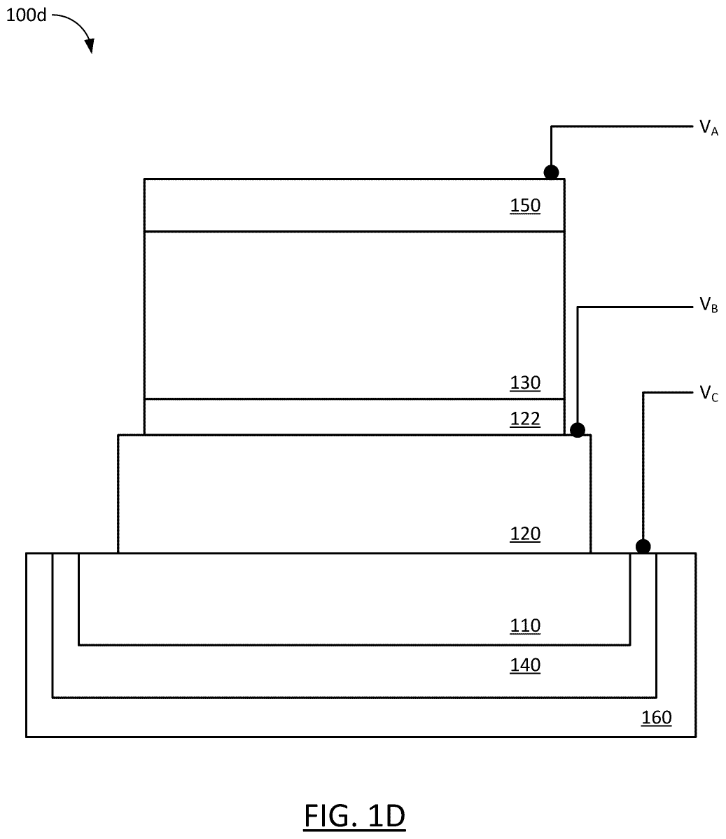

FIG. 1A shows a cross-sectional view of a photodetector 100a. The photodetector 100a includes a first photo-detecting layer 110, a second photo-detecting layer 120, and a third photo-detecting layer 130. The first photo-detecting layer 110 includes a first absorption region configured to absorb light in the visible spectrum and/or the NIR spectrum (e.g., 400 nm to 700 nm or any suitable wavelength range by design). As an example, the first photo-detecting layer 110 may be silicon (Si).

The second photo-detecting layer 120 is formed over the first photo-detecting layer 110, where the second photo-detecting layer 120 includes a second absorption region configured to absorb light in the NIR spectrum and/or the SWIR spectrum (e.g., 700 nm to 1600 nm or any suitable wavelength range by design) in a shorter wavelength range. As an example, the second photo-detecting layer 120 may be germanium (Ge), or GeₓSi₁₋ₓ, where 0<x≤1.

The third photo-detecting layer 130 is formed over the second photo-detecting layer 120, where the third photo-detecting layer 130 includes a third absorption region configured to absorb light in the SWIR spectrum and/or MIR spectrum (e.g., 1600 nm to 2400 nm or any suitable wavelength range by design) in a longer wavelength range that is different from the shorter wavelength range. Referring to FIG. 1, in some implementations, the third photo-detecting layer 130 may be formed using a single layer of germanium-tin (GeSn), or Ge_{1-x-y}SiₓSn_{y}, or a composition of alternating strain-balanced superlattice layers (e.g., Ge₁₋ₓSiₓ/Ge_{1-y}Sn_{y}). In some implementations, one or more of the first photo-detecting layer 110, the second photo-detecting layer 120, and/or the third photo-detecting layer 130 may be p-doped or n-doped. In some implementations, the order of the material is arranged such that the high energy photons are absorbed first, and the low energy photons are absorbed last.

FIG. 1B shows a cross-sectional view of a photodetector 100b. Similar to photodetector 100a, the photodetector 100b includes the first photo-detecting layer 110, the second photo-detecting layer 120, and the third photo-detecting layer 130. The photodetector 100b further includes a first buffer layer 122, which may include group IV materials (e.g., C, Si, Ge, Sn) or group III-V materials (e.g., B, Al, Ga, In, N, P, As, Sb). The first buffer layer 122 may further improve the lattice matching and/or strain balance between the second photo-detecting layer 120 and the third photo-detecting layer 130.

FIG. 1C illustrates a cross-sectional view of a photodetector 100c. The photodetector 100c includes layers that are similar to those described in the photodetector 100b, and further includes a first carrier-collection layer 140 and a second carrier-collection layer 150. In general, the first carrier-collection layer 140 is configured to collect and to output free-carriers of a first polarity, and the second carrier-collection layer 150 is configured to collect and to output free-carriers of a second polarity.

As an example, the first carrier-collection layer 140 may be an n-doped silicon layer configured to collect and to output electrons, and the second carrier-collection layer 150 may be a p-doped germanium layer configured to collect and to output holes. The second carrier-collection layer 150 (e.g., p-doped germanium) is coupled to a first control voltage V_{A}. The second photo-detecting layer 120 (e.g., p-doped germanium) is coupled to a second control voltage V_{B}. The first carrier-collection layer 140 (e.g., n-doped silicon) is coupled to a third control voltage V_{C}.

In some implementations, the photodetector 100c may operate under two modes that are controlled by the control voltages V_{A}, V_{B}, and V_{C}. In a first mode, the first control voltage V_{A} operates under a lower voltage value than the second control voltage V_{B}, and the second control voltage V_{B} operates under a lower voltage value than the third control voltage V_{C}. Incident photons in the first spectrum are absorbed by the first photo-detecting layer 110, where the generated electrons drift to the first carrier-collection layer 140 (due to the electric field created by the voltage difference between V_{B} and V_{C}) and can be read by external circuitry (not shown) for further processing. Moreover, incident photons in the second spectrum are absorbed by the second photo-detecting layer 120, where the generated electrons drift from the second photo-detecting layer 120 to the photo-detecting layer 110 and then to the first carrier-collection layer 140 (due to the electric field created by the voltage difference between V_{B} and V_{C}) and can be read by external circuitry (not shown) for further processing. Lastly, incident photons in the third spectrum are absorbed by the third photo-detecting layer 130, where the generated electrons drift from the third photo-detecting layer 130 to the first carrier-collection layer 140 (due to the electric field created by the voltage difference between V_{A} and V_{C}), and can be read by external circuitry (not shown) for further processing.

In a second mode, the first control voltages V_{A} operates under an equal or higher voltage value than the second control voltage V_{B}, and the second control voltage V_{B} operates under a lower voltage value than the third control voltage V_{C}. Similar to the first mode, the incident photons in the first spectrum and the second spectrum are absorbed by the first photo-detecting layer 110 and the second photo-detecting layer 120, respectively, where the generated electrons are collected by the first carrier-collection layer 140 (due to the electric field created by the voltage difference between V_{B} and V_{C}) and can be read by external circuitry (not shown) for further processing. However, in the second mode, incident photons in the third spectrum are absorbed by the third photo-detecting layer 130, where the generated electrons drift from the third photo-detecting layer 130 to the second carrier-collection layer 150 (due to the electric field created by the voltage difference between V_{A} and V_{C}), and are not read by external circuitry (not shown) coupled to the first carrier-collection layer 140. Accordingly, by controlling the control voltages, it is possible to filter out the detection of a particular detection spectrum (e.g., the third spectrum).

In some implementations, the photodetector 100c may operate under a mode that are controlled by the control voltages V_{A} and V_{C}, where the control voltage V_{B} is floating, such that the photodetector 100c operates as a two-terminal biasing device.

FIG. 1D illustrates a cross-sectional view of a photodetector 100d, which can be an example implementation of the photodetector 100c on a semiconductor substrate. The photodetector 100d includes a semiconductor substrate 160 (e.g., silicon substrate). The first carrier-collection layer 140 may be formed in the semiconductor substrate 160 by doping the semiconductor substrate 160 to the designed dopant concentration (e.g., n-doped silicon). The first photo-detecting layer 110 may then be formed in the semiconductor substrate 160 by doping the semiconductor substrate 160 to the designed dopant concentration (e.g., intrinsic or lightly n-doped or lightly p-doped silicon). The second photo-detecting layer 120 may then be formed by first forming a mesa over the semiconductor substrate 160 (e.g., by etching), and then forming the designed material and dopant concentration (e.g., p-doped germanium). In some implementations, the first buffer layer 122 may be optionally formed after forming the second photo-detecting layer 120. The third photo-detecting layer 130 may then be formed by forming a single layer of germanium-tin (GeSn) or Ge_{1-x-y}SiₓSn_{y}. The second carrier-collection layer 150 (e.g., p-doped germanium) may then be formed over the third photo-detecting layer 130. In some implementations, a portion of the second photo-detecting layer 120, the optional first buffer layer 122, the third photo-detecting layer 130, and the second carrier-collection layer 150, is embedded in the semiconductor substrate 160 by first forming a trench over the semiconductor substrate 160 (e.g., by etching), and then forming the designed material and dopant concentration.

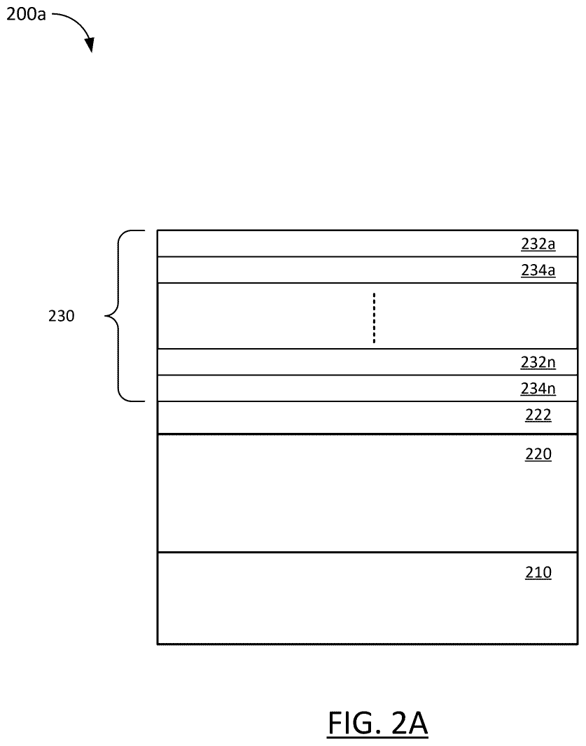

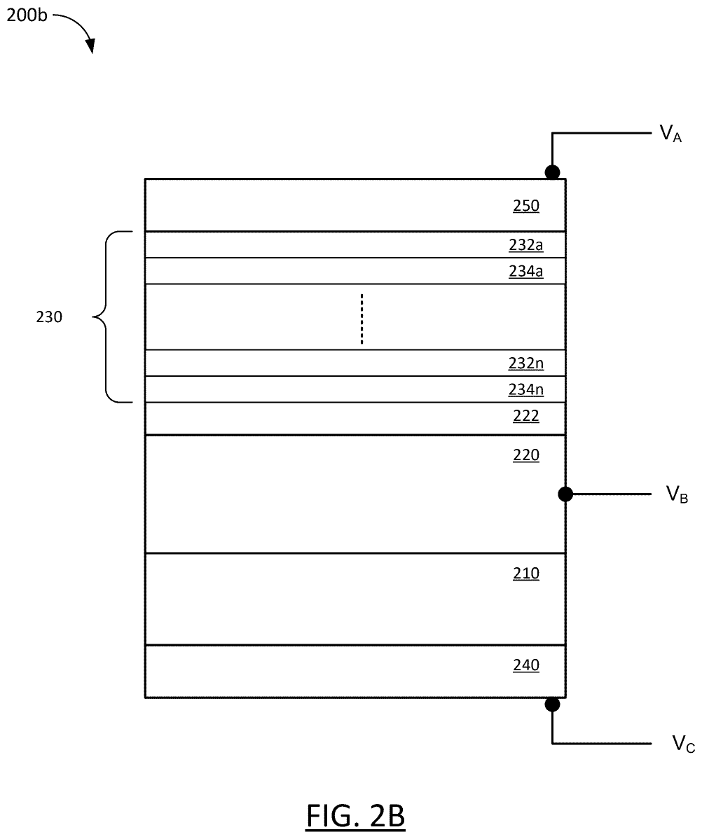

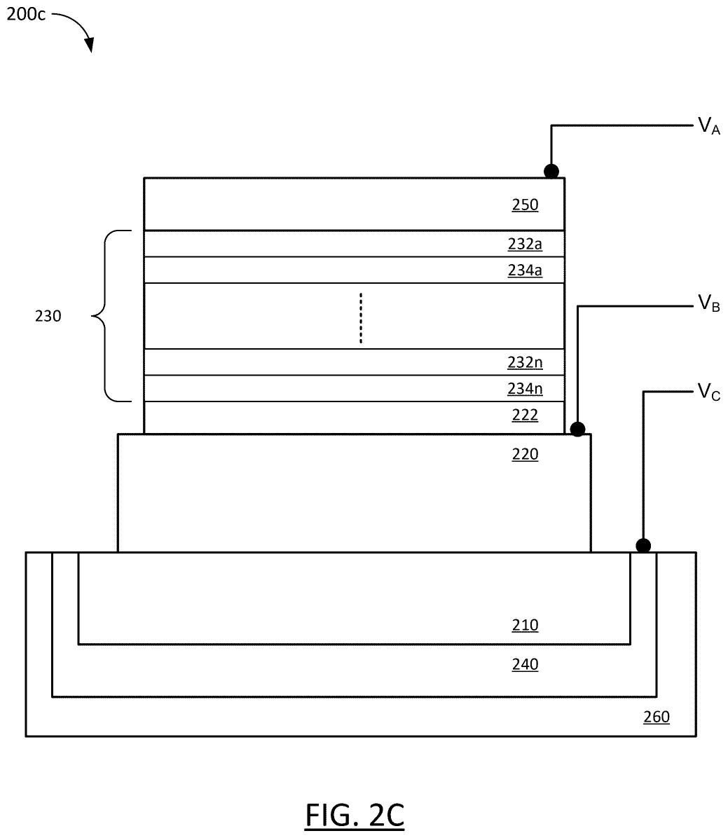

FIG. 2A shows a photodetector 200a. The photodetector 200a includes a first photo-detecting layer 210, a second photo-detecting layer 220, and a third photo-detecting layer 230. The first photo-detecting layer 210 and the second photo-detecting layer 220 are similar to the first photo-detecting layer 110 and the second photo-detecting layer 120 described in reference to FIG. 1. The third photo-detecting layer 230 includes a third absorption region configured to absorb light in the SWIR spectrum and/or MIR spectrum. In some implementations, the third photo-detecting layer 230 may be formed using a strain-balanced Ge₁₋ₓSnₓ/Ge_{1-y}Si_{y} multi-layer structure 232a/234a-232n/234n, where 0<x≤0.3, 0<y≤1, and where n is an integer greater than one. In some implementations, the n-th layer of the multilayer structure may be a single layer of Ge₁₋ₓSnₓ or Ge_{1-y}Si_{y}. In general, a strain-balanced multi-layer structure is designed to maintain lattice matching and minimize strain between different layers to improve device performance such as to avoid defects and dislocations that can negatively impact device performance, to engineer the bandgap energy across the structure, and to improve efficiency.

In some implementations, one or more of the first photo-detecting layer 210, the second photo-detecting layer 220, and/or the third photo-detecting layer 230 may be p-doped or n-doped. For example, the second photo-detecting layer 220 may be a germanium layer that is p-doped (e.g., with a gradient p-doped profile that decreases in the direction from the third photo-detecting layer 230 towards the first photo-detecting layer 210). As another example, the first photo-detecting layer 210 may be a silicon layer that is intrinsic or lightly n-doped or lightly p-doped. In some implementations, the order of the material is arranged such that the high energy photons are absorbed first, and the low energy photons are absorbed last.

In some implementations, the photodetector 200a includes a first buffer layer 222, which may include group IV materials (e.g., C, Si, Ge, Sn) or group III-V materials (e.g., B, Al, Ga, In, N, P, As, Sb). The first buffer layer 222 may further improve the lattice matching and/or strain balance between the second photo-detecting layer 220 and the third photo-detecting layer 230.

FIG. 2B illustrates a cross-sectional view of a photodetector 200b. The photodetector 200b includes layers that are similar to those described in the photodetector 200a, and further includes a first carrier-collection layer 240 and a second carrier-collection layer 250. In general, the first carrier-collection layer 240 is configured to collect and to output free-carriers of a first polarity, and the second carrier-collection layer 250 is configured to collect and to output free-carriers of a second polarity.

As one example, the photodetector 200b may include a first photo-detecting layer 210 that is a silicon layer that is configured to absorb light in a first spectrum (e.g., the visible and/or NIR spectrum including 400 nm-700 nm). The first photo-detecting layer 210 may be intrinsic or lightly n-doped or lightly p-doped (e.g., less than 10¹⁶ cm⁻³). The second photo-detecting layer 220 may be a germanium layer that is configured to absorb light in a second spectrum (e.g., the NIR and/or SWIR spectrum including 700 nm-1600 nm). The second photo-detecting layer 220 may be p-doped with a doping concentration higher than that of the first photo-detecting layer 210 (e.g., more than 10¹⁶ cm⁻³). The third photo-detecting layer 230 may be a multi-layer strain-balanced Ge₁₋ₓSnₓ/Ge_{1-y}Si_{y} superlattice structure 232a/234a-232n/234n that is configured to absorb light in a third spectrum (e.g., the SWIR and/or MIR spectrum including 1600 nm-2400 nm). For this example, the second photo-detecting layer 220 is formed over the first photo-detecting layer 210, and the third photo-detecting layer 230 is formed over the second photo-detecting layer 220 without the first buffer layer 222.

Here, the first carrier-collection layer 240 is an n-doped silicon layer configured to collect and to output electrons, and the second carrier-collection layer 250 is a p-doped germanium layer configured to collect and to output holes. The second carrier-collection layer 250 (p-doped germanium) is coupled to a first control voltage V_{A}. The second photo-detecting layer 220 (p-doped germanium) is coupled to a second control voltage V_{B}. The first carrier-collection layer 240 (n-doped silicon) is coupled to a third control voltage V_{C}.

In some implementations, the photodetector 200b may operate under two modes that are controlled by the control voltages V_{A}, V_{B}, and V_{C}. In a first mode, the first control voltage V_{A} operates under a lower voltage value than the second control voltage V_{B}, and the second control voltage V_{B} operates under a lower voltage value than the third control voltage V_{C}. Incident photons in the first spectrum are absorbed by the first photo-detecting layer 210, where the generated electrons drift to the first carrier-collection layer 240 (due to the electric field created by the voltage difference between V_{B} and V_{C}) and can be read by external circuitry (not shown) for further processing. Moreover, incident photons in the second spectrum are absorbed by the second photo-detecting layer 220, where the generated electrons drift from the second photo-detecting layer 220 to the photo-detecting layer 210 and then to the first carrier-collection layer 240 (due to the electric field created by the voltage difference between V_{B} and V_{C}) and can be read by external circuitry (not shown) for further processing. Lastly, incident photons in the third spectrum are absorbed by the third photo-detecting layer 230, where the generated electrons drift from the third photo-detecting layer 230 to the first carrier-collection layer 240 (due to the electric field created by the voltage difference between V_{A} and V_{C}), and can be read by external circuitry (not shown) for further processing.

In a second mode, the first control voltages V_{A} operates under an equal or higher voltage value than the second control voltage V_{B}, and the second control voltage V_{B} operates under a lower voltage value than the third control voltage V_{C}. Similar to the first mode, the incident photons in the first spectrum and the second spectrum are absorbed by the first photo-detecting layer 210 and the second photo-detecting layer 220, respectively, where the generated electrons are collected by the first carrier-collection layer 240 (due to the electric field created by the voltage difference between V_{B} and V_{C}) and can be read by external circuitry (not shown) for further processing. However, in the second mode, incident photons in the third spectrum are absorbed by the third photo-detecting layer 230, where the generated electrons drift from the third photo-detecting layer 230 to the second carrier-collection layer 250 (due to the electric field created by the voltage difference between V_{A} and V_{C}), and are not read by external circuitry (not shown) coupled to the first carrier-collection layer 240. Accordingly, by controlling the control voltages, it is possible to filter out the detection of a particular detection spectrum (e.g., the third spectrum).

In some implementations, the photodetector 200b may operate under a mode that are controlled by the control voltages V_{A} and V_{C}, where the control voltage V_{B} is floating, such that the photodetector 200b operates as a two-terminal biasing device.

FIG. 2C illustrates a cross-sectional view of a photodetector 200c, which can be an example implementation of the photodetector 200b on a semiconductor substrate. The photodetector 200c includes a semiconductor substrate 260 (e.g., silicon substrate). The first carrier-collection layer 240 may be formed in the semiconductor substrate 260 by doping the semiconductor substrate 260 to the designed dopant concentration (e.g., n-doped silicon). The first photo-detecting layer 210 may then be formed in the semiconductor substrate 260 by doping the semiconductor substrate 260 to the designed dopant concentration (e.g., intrinsic or lightly n-doped or lightly p-doped silicon). The second photo-detecting layer 220 may then be formed by first forming a mesa over the semiconductor substrate 260 (e.g., by etching), and then forming the designed material and dopant concentration (e.g., p-doped germanium). In some implementations, the first buffer layer 222 may be optionally formed after forming the second photo-detecting layer 220 depending on the strain properties of the different layers. The third photo-detecting layer 230 may then be formed by forming alternating layers of strain-balanced Ge₁₋ₓSnₓ/Ge_{1-y}Si_{y} multi-layer structure 232a/234a-232n/234n. The second carrier-collection layer 250 (e.g., p-doped germanium) may then be formed over the third photo-detecting layer 230. In some implementations, a portion of the second photo-detecting layer 220, the optional first buffer layer 222, the third photo-detecting layer 230, and the second carrier-collection layer 250, is embedded in the semiconductor substrate 260 by first forming a trench over the semiconductor substrate 260 (e.g., by etching), and then forming the designed material and dopant concentration.

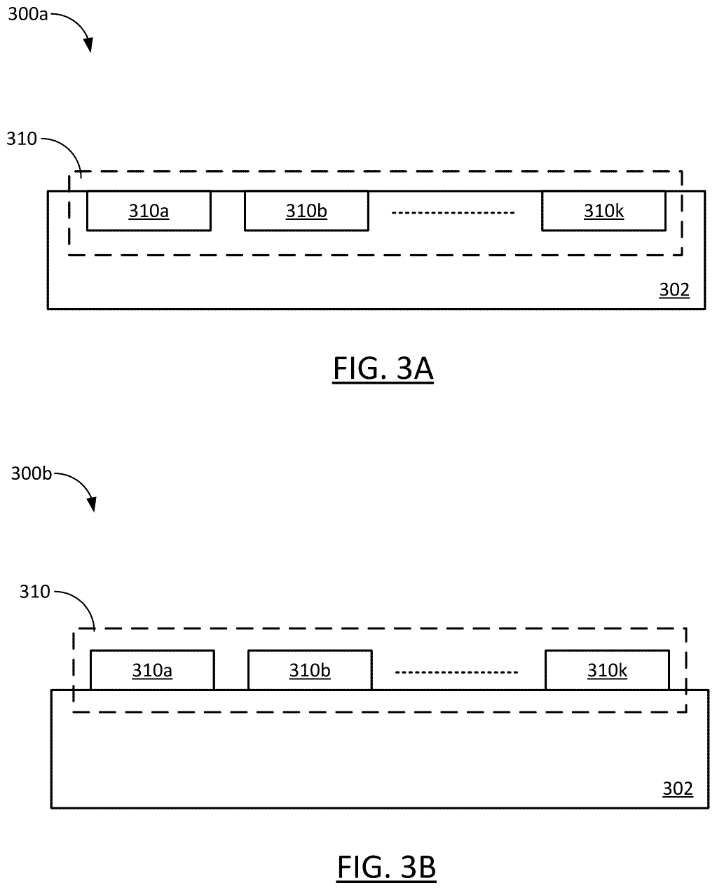

FIGS. 3A and 3B show examples of a photodetector 300a/300b. The photodetector 300a/300b includes a substrate 302 (e.g., silicon or another substrate material) and k pixels 310a-310k along a direction, where each of the k pixels 310a-310k may be a photodiode, an avalanche photodiode, or a single-photon avalanche photodiode implemented using the photodetector 100a/100b/100c/100d or the photodetector 200a/200b/200c described in reference to FIGS. 1A-1D and 2A-2C, respectively. Referring to FIG. 3A, in some implementations, the k pixels 310a-310k may be partially or fully embedded in the substrate 302 (e.g., epitaxially grown in an etched trench in the substrate 302). Referring to FIG. 3B, in some implementations, the k pixels 310a-310k may be formed on a surface of the substrate 302 (e.g., epitaxially grown over the surface of the substrate 302, followed by an etch to form the pixels).

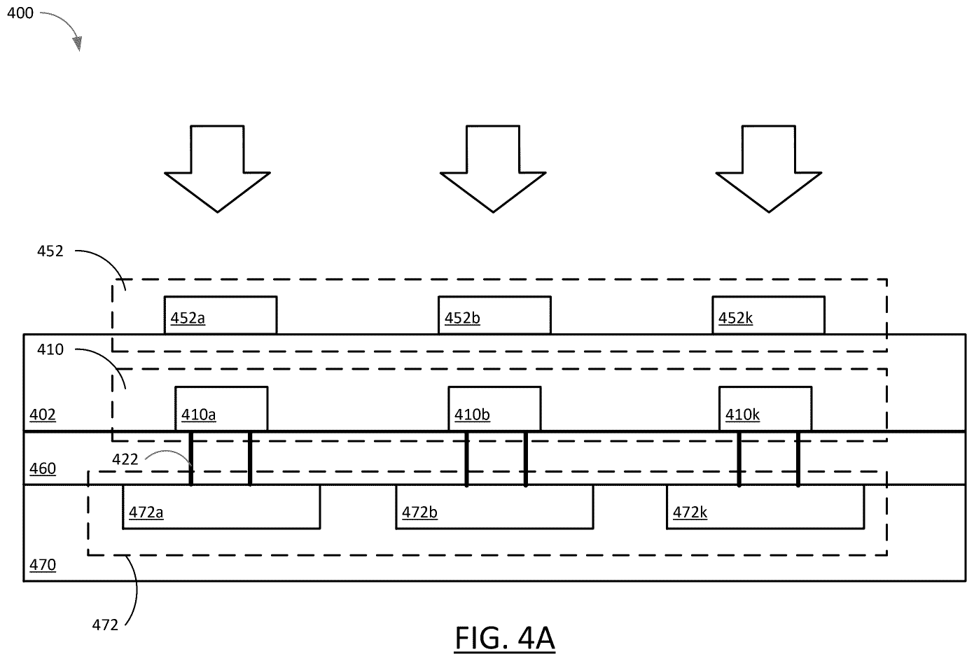

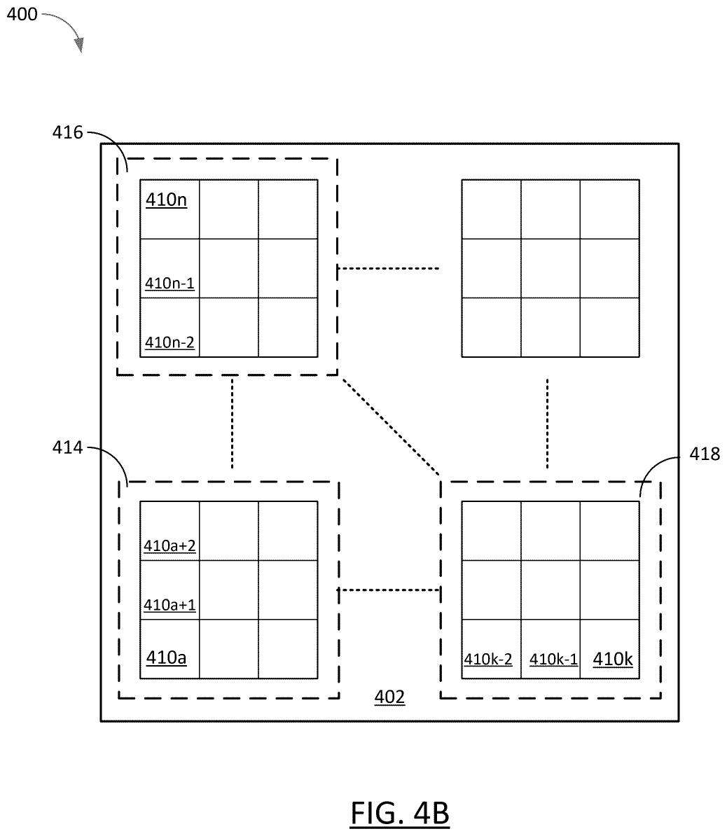

FIG. 4A shows an example of a photodetector 400. The photodetector 400 includes a first substrate 402 (e.g., silicon substrate) having k pixels 410a-410k (e.g., k pixels 310a-310k described in reference to FIG. 3A or 3B) along a direction that is directly or flipped bonded to a second substrate 470 (e.g., a silicon substrate) having circuitry 472. The bonding interface 460 may be a dielectric material (e.g., oxide). In some implementations, the circuitry 472 may include k individual circuitry that each is electrically coupled to a corresponding pixel 410 via wires 422. The circuitry 472 may be readout circuitry that is configured to collect the electrical carriers (e.g., electrons or holes) generated from the pixels 410, or processing circuitry that is configured to process the collected carriers to determine useful information (e.g., proximity information, depth information, material detection information, bio-signal information, etc.) related to an object or an environment sensed by the photodetector 400.

In some implementations, the photodetector 400 may include an optical structure 452. The optical structure 452 may be one or more layers of structures that focuses, directs, filters, passes, or otherwise manipulates an optical signal that enters the k pixels 410. In some implementations, the optical structure 452 may include k optical structures 452a-452k that each is optically coupled to a corresponding pixel 410. For example, an optical structure 452a may be a band pass filter that is implemented using a meta-surface, a Fabry-Perot interferometer, or an absorption material. As another example, an optical structure 452a may be a combination of a band pass filter and an optical lens, where the band pass filter may be implemented using a meta-surface, a Fabry-Perot interferometer, or an absorption material, and the optical lens may be implemented using a meta-surface or a convex lens (e.g., silicon lens or polymer lens). In some implementations, different optical structures may be configured to pass a different wavelength range of light. For example, the optical structures 452a, 452b, and 452c may be configured to pass a visible-NIR light spectrum (e.g., 400 nm-700 nm), a NIR-SWIR light spectrum (e.g., 700 nm-1600 nm), and a SWIR-MIR light (e.g., 1600 nm-2400 nm), respectively.

FIG. 4B illustrates an example of a top view of the photodetector 400 having a two-dimensional array of k×n pixels. In some implementations, pixels may be logically binned by the associated bandpass filters (e.g., optical structure 452). As an example, a bandpass filter that passes visible-NIR light spectrum may be formed over a 3×3 grouping of pixels (or pixel groups) 414, such that the pixel group 414 is configured to detect light in the visible-NIR light spectrum. Moreover, a bandpass filter that passes a NIR-SWIR light spectrum may be formed over a 3×3 grouping of pixels 416, such that the pixel group 416 is configured to detect light in the NIR-SWIR light spectrum. A bandpass filter that passes a SWIR-MIR light spectrum may be formed over a 3×3 grouping of pixels 418, such that the pixel group 418 is configured to detect light in the SWIR-MIR light spectrum. Here, the circuitry 472 may be configured to separately control each grouping of pixels, which may simplify the overall control of the photodetector. In some implementations, the circuitry 472 may be configured to dynamically control how the pixel groups operate over time in order to increase the flexibility of the device. For example, all pixel groups may be configured to operate at the same time to maximize the detectable range. As another example, different pixel groups may be configured to operate at different times to reduce power usage.

As another example, a bandpass filter that passes visible-NIR light spectrum may be formed over pixels including 410a, 410n−2, and 410k−2, such that the pixel group is configured to detect light in the visible-NIR light spectrum. Moreover, a bandpass filter that passes a NIR-SWIR light spectrum may be formed over pixels including 410a+1, 410n−1, and 410k−1, such that the pixel group is configured to detect light in the NIR-SWIR light spectrum. A bandpass filter that passes a SWIR-MIR light spectrum may be formed over pixels 410a+2, 410n, and 410k, such that the pixel group is configured to detect light in the SWIR-MIR light spectrum. Here, such arrangement may allow the photodetector 400 to have a larger detectable area for different light spectra. In some implementations, the circuitry 472 may be configured to dynamically control how the pixel groups operate over time in order to increase the flexibility of the device as described above.

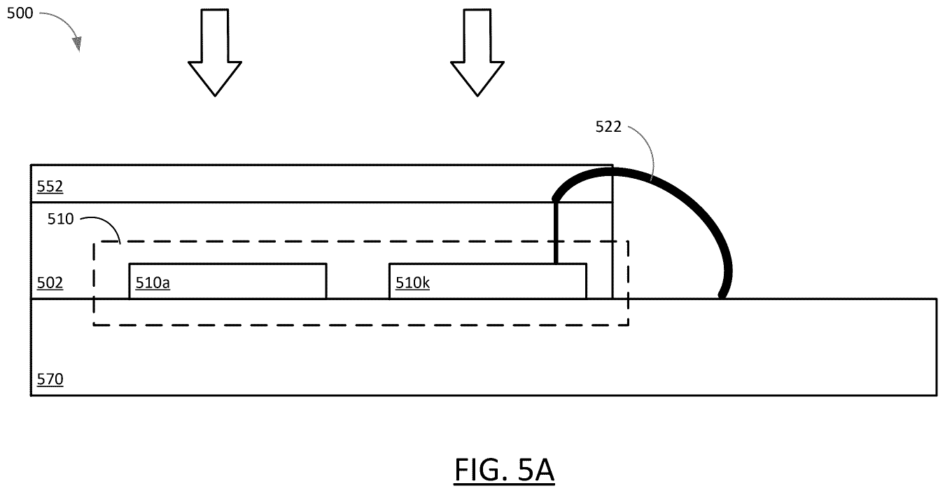

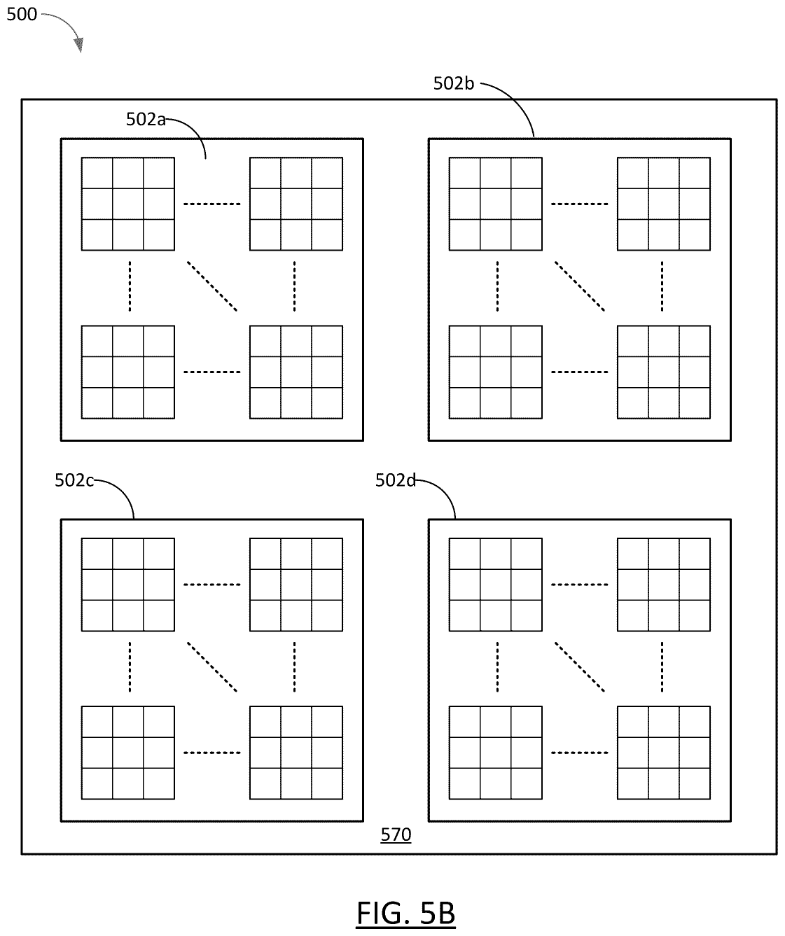

FIG. 5A shows an example of a photodetector 500. The photodetector 500 includes a first substrate 502 (e.g., silicon substrate) having k pixels 510a-510k (e.g., k pixels 310a-310k described in reference to FIG. 3A or 3B) along a direction that is packaged with a discrete application specific integrated circuit (ASIC) 570 via wire bond, flip-chip bond, or another suitable packaging means. In some implementations, the photodetector 500 may include an optical structure 552 (e.g., an optical structure 452).

FIG. 5B illustrates an example of a top view of the photodetector 500 having a two-dimensional array of pixels, similar to that of the photodetector 400. Here, multiple substrates 502a-502d are packaged with the discrete ASIC chip 570, where each of the multiple substrates 502a-502d includes a two-dimensional array of pixels. The discrete ASIC chip 570 may be configured to control the operation of the pixels in the substrates 502a-502d as described in FIG. 5A. In some implementations, the circuitry on the discrete ASIC chip 570 may be configured to dynamically control how the pixel groups operate over time in order to increase the flexibility of the device, similar to those described in reference to FIGS. 4A and 4B. In some implementations, an optical structure 552 may be formed over each substrate 502 to manipulate the optical signal to be detected by the pixel array, similar to those described in reference to FIGS. 4A and 4B

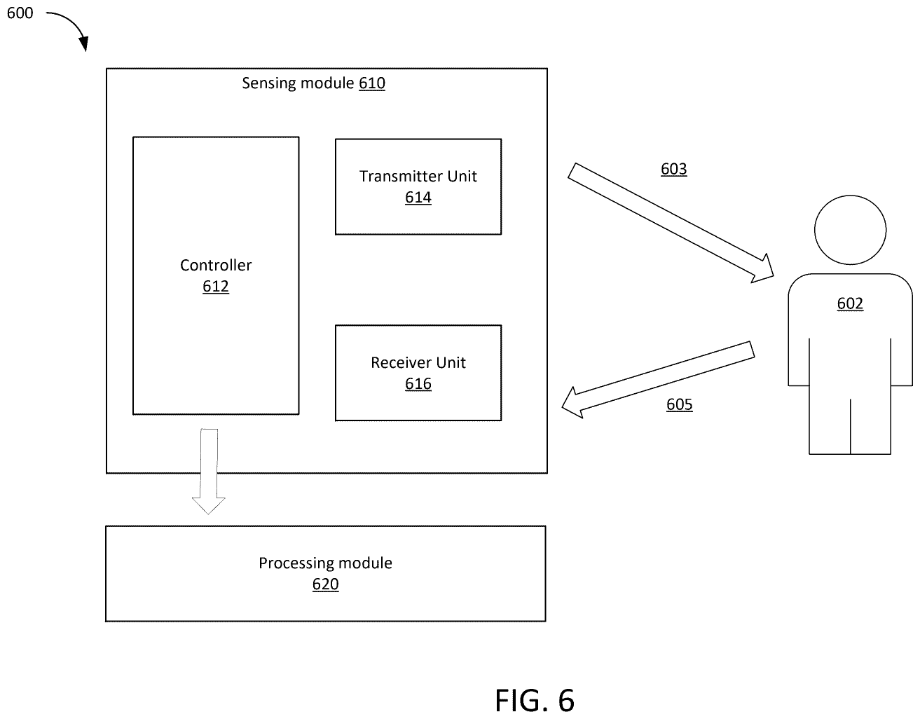

FIG. 6 is a block diagram of an example of a sensing system 600. The sensing system 600 may include a sensing module 610 and a processing module 620 configured process data associated with a detected object 602. The sensing system 600 or the sensing module 610 may be implemented on a mobile device (e.g., a smartphone, a tablet, vehicle, drone, etc.), an ancillary device (e.g., a wearable device) for a mobile device, a computing system on a vehicle or in a fixed facility (e.g., a factory), a robotics system, a surveillance system, or any other suitable device and/or system.

The sensing module 610 includes a transmitter unit 614, a receiver unit 616, and a controller 612. During operation, the transmitter unit 614 may emit an emitted light 603 toward a target object 602. The receiver unit 616 may receive reflected light 605 reflected from the target object 602. The controller 612 may drive at least the transmitter unit 614 and the receiver unit 616. In some implementations, the receiver unit 616 and the controller 612 are implemented on one semiconductor chip, such as a system-on-a-chip (SoC). In some cases, the transmitter unit 614 is implemented by two different semiconductor chips, such a laser emitter chip on III-V substrate and a Si laser driver chip on Si substrate.

The transmitter unit 614 may include one or more light sources, control circuitry controlling the one or more light sources, and/or optical structures for manipulating the light emitted from the one or more light sources. In some embodiments, the light source may include one or more light emitting diodes (LEDs) or vertical-cavity surface-emitting lasers (VCSELs) emitting light that can be absorbed by the absorption region in the optical sensing apparatus. For example, the one or more LEDs or VCSEL may emit light with a peak wavelength within the visible, NIR, SWIR, MIR, or any other applicable wavelengths. In some embodiments, the emitted light from the light sources may be collimated by the one or more optical structures. For example, the optical structures may include one or more collimating lens.

The receiver unit 616 may include one or more optical sensing apparatus, e.g., any one or more of photodetectors 100a/100b/100c/100d, 200a/200b/200c, 300a/300b, 400, 500, or 700a/700b. The receiver unit 616 may further include a control circuitry for controlling the control circuitry and/or optical structures for manipulating the light reflected from the target object 602 toward the one or more optical sensing apparatus. In some implementations, the optical structures include one or more lens that receive a collimated light and focus the collimated light towards the one or more optical sensing apparatus.

The processing module 620 may be implemented to perform in applications such as proximity sensing, bio-signal detection, material recognition, facial recognition, eye-tracking, gesture recognition, 3-dimensional model scanning/video recording, motion tracking, autonomous vehicles, and/or augmented/virtual reality. Using glucose detection as an example of hyperspectral detection applications, a SPAD (single PD or PD array) implemented using a photodetector (e.g., photodetectors 100a/100b/100c/100d, 200a/200b/200c, 300a/300b, 400, 500, or 700a/700b) can be used to detect NIR, SWIR, and/or MIR optical signals reflected from a target (e.g., human skin), and the processing module 620 may be configured to determine glucose information associated with the target based on the detected optical signals. In some implementations, the sensing system 600 may be configured to detect the optical signals over different time points. For example, the optical signals associated with different wavelengths may be reflected at different time points based on the penetration depth into the skin. The SPAD may be configured to detect the optical signals associated with different wavelengths at different times, and the processing module 620 may be configured to differentiate the wavelengths of the reflected optical signals based on arrival times without the need for multiple wavelength filters. As another example, a SPAD array may be implemented to include multiple wavelength filters (e.g., as described in reference to FIG. 4B and FIG. 5B. The SPAD may be configured to detect the optical signals associated with different wavelengths at different pixels, and the processing module 620 may be configured to differentiate the wavelengths of the reflected optical signals based on the pixel arrangement. In some implementations, depending on the desirable detection wavelengths, the SPAD may not need to include the third photo-detecting layer 130 configured to absorb light in the second range of the shortwave infrared spectrum.

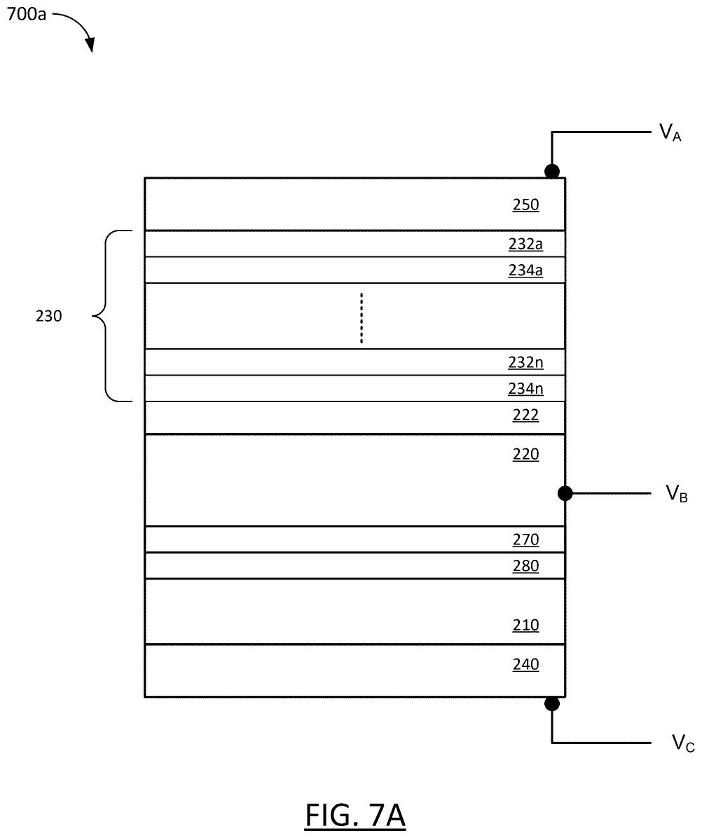

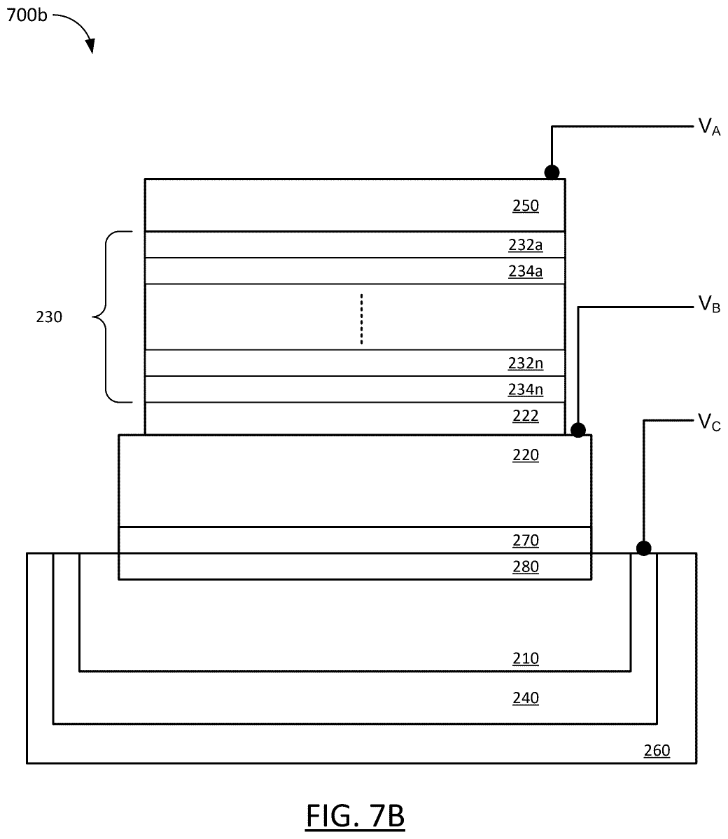

FIG. 7A illustrates a cross-sectional view of a photodetector 700a that can operate as a PD, an APD, or a SPAD. The photodetector 700a includes layers that are similar to those described in the photodetector 200b (in reference to FIG. 2B), and further includes an interface dopant layer 280 and a second buffer layer 270. In general, the second buffer layer 270 is configured to reduce a dark current associated with the second photo-detecting layer 220, and the interface dopant layer 280 is configured to provide an avalanche gain in the first photo-detecting layer 210 between the interface dopant layer 280 and the first carrier-collection layer 240.

As one example, the photodetector 700a may include a first photo-detecting layer 210 that is a silicon layer configured to absorb light in a first spectrum (e.g., the visible and/or NIR spectrum including 400 nm-700 nm). The first photo-detecting layer 210 may be intrinsic or lightly n-doped or lightly p-doped (e.g., less than 10¹⁶ cm⁻³). The second photo-detecting layer 220 may be a germanium layer that is configured to absorb light in a second spectrum (e.g., the NIR and/or SWIR spectrum including 700 nm-1600 nm). The second photo-detecting layer 220 may be p-doped with a doping concentration higher than that of the first photo-detecting layer 210 (e.g., more than 10¹⁶ cm⁻³).

In some implementations, the third photo-detecting layer 230 may be a multi-layer strain-balanced Ge₁₋ₓSnₓ/Ge_{1-y}Si_{y} superlattice structure 232a/234a-232n/234n that is configured to absorb light in a third spectrum (e.g., the SWIR and/or MIR spectrum including 1600 nm-2400 nm). For this example, the second photo-detecting layer 220 is formed over the first photo-detecting layer 210, and the third photo-detecting layer 230 is formed over the second photo-detecting layer 220 without the first buffer layer 222. In some other implementations, the third photo-detecting layer 230 may be replaced by the third photo-detecting layer 130 as described in reference to FIGS. 1A-1D (e.g., a single layer of germanium-tin (GeSn), or Ge_{1-x-y}SiₓSn_{y}).

Here, the first carrier-collection layer 240 is an n-doped silicon layer configured to collect and to output electrons, and the second carrier-collection layer 250 is a p-doped germanium layer configured to collect and to output holes. The second carrier-collection layer 250 is coupled to a first control voltage V_{A}. The second photo-detecting layer 220 is coupled to a second control voltage V_{B}. The first carrier-collection layer 240 is coupled to a third control voltage V_{C}.

Moreover, an interface dopant layer 280 may be formed over the first photo-detecting layer 210. For this example, the interface dopant layer 280 is a p-doped silicon layer that provides an avalanche gain in the first photo-detecting layer 210 between the interface dopant layer 280 and the first carrier-collection layer 240. A second buffer layer 270 may be formed over the interface dopant layer 280, where the second buffer layer 270 may be intrinsic or lightly n-doped or lightly-p-doped silicon.

In some implementations, the photodetector 700a may operate under two modes that are controlled by the control voltages V_{A}, V_{B}, and V_{C}, similar to the two modes previously described in reference to FIG. 2B. Moreover, under each mode, the photodetector 700a may operate as a PD, an APD, or a SPAD. For example, if the voltage difference between V_{B} and V_{C} matches the required operating voltage point for a unity-gain in the first photo-detecting layer 210, the photodetector 700a may operate as a PD. Moreover, if the voltage difference between V_{B} and V_{C} is below the avalanche breakdown condition for the first photo-detecting layer 210, the photodetector 700a may operate as an APD. Lastly, if the voltage difference between V_{B} and V_{C} is over the avalanche breakdown condition for the first photo-detecting layer 210, the photodetector 700a may operate as an SPAD.

In some implementations, the photodetector 700a may operate under a mode that are controlled by the control voltages V_{A} and V_{C}, where the control voltage V_{B} is floating, such that the photodetector 700a operates as a two-terminal biasing device.

FIG. 7B illustrates a cross-sectional view of a photodetector 700b, which can be an example implementation of the photodetector 700a on a semiconductor substrate. The photodetector 700b includes a semiconductor substrate 260 (e.g., silicon substrate). The first carrier-collection layer 240 may be formed in the semiconductor substrate 260 by doping the semiconductor substrate 260 to the designed dopant concentration (e.g., n-doped silicon). The first photo-detecting layer 210 may then be formed in the semiconductor substrate 260 by doping the semiconductor substrate 260 to the designed dopant concentration (e.g., intrinsic or lightly n-doped or lightly p-doped silicon). The second photo-detecting layer 220 may then be formed by first forming a mesa in the semiconductor substrate 260 (e.g., by etching), and then forming the designed material and dopant concentration (e.g., p-doped germanium). The interface dopant layer 280 may be formed (e.g., by doping p-dopants in the semiconductor substrate 260) after the mesa formation but prior to the deposition of the second photo-detecting layer 220. The second buffer layer 270 may be formed in the semiconductor substrate 260 by controlling the doping depth and profile of the interface dopant layer 280 In some implementations, the first buffer layer 222 may be optionally formed after forming the second photo-detecting layer 220 depending on the strain properties of the different layers. The third photo-detecting layer 230 may then be formed by forming alternating layers of strain-balanced Ge₁₋ₓSnₓ/Ge_{1-y}Si_{y} multi-layer structure 232a/234a-232n/234n. The second carrier-collection layer 250 (e.g., p-doped germanium) may then be formed over the third photo-detecting layer 230. In some implementations, a portion of the second photo-detecting layer 220, the optional first buffer layer 222, the third photo-detecting layer 230, and the second carrier-collection layer 250, is embedded in the semiconductor substrate 260 by first forming a trench over the semiconductor substrate 260 (e.g., by etching), and then forming the designed material and dopant concentration.

As used herein and not otherwise defined, the terms “substantially” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

While the concepts have been described by way of examples and in terms of embodiments, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An optical sensing apparatus comprising:
a first absorption region configured to absorb light in at least a first spectrum with visible or near infrared wavelengths;
a second absorption region formed over the first absorption region, the second absorption region configured to absorb light in at least a second spectrum with near infrared or shortwave infrared wavelengths; and
a third absorption region formed over the second absorption region, the third absorption region configured to absorb light in at least a third spectrum with shortwave infrared or mid-wave infrared wavelengths.

2. The optical sensing apparatus of claim 1, wherein the first absorption region comprises silicon, and wherein the second absorption region comprises germanium.

3. The optical sensing apparatus of claim 2, wherein the third absorption region comprises multiple strain-balanced layers of germanium-silicon compounds and germanium-tin compounds.

4. The optical sensing apparatus of claim 2, wherein the third absorption region comprises a layer of germanium-tin compounds.

5. The optical sensing apparatus of claim 1, further comprising a first substrate and an optical structure,
wherein the first substrate is arranged between the optical structure and the first absorption region, and wherein the optical structure comprises a metalens or a curved lens.

6. The optical sensing apparatus of claim 5, further comprising a second substrate that comprises circuitry configured to collect electric carriers generated by the first absorption region, the second absorption region, or the third absorption region.

7. The optical sensing apparatus of claim 1, further comprising a first buffer layer formed between the second absorption region and the third absorption region.

8. The optical sensing apparatus of claim 1, further comprising:
a first carrier-collection layer configured to collect and to output free-carriers of a first polarity, and
a second carrier-collection layer configured to collect and to output free-carriers of a second polarity,
wherein the second carrier-collection layer is coupled to a first control voltage, wherein the second photo-detecting region is coupled to a second control voltage, and wherein the first carrier-collection layer is coupled to a third control voltage.

9. The optical sensing apparatus of claim 8, wherein, during an operation of the optical sensing apparatus, the first control voltage operates under a lower voltage value than the second control voltage, and the second control voltage operates under a lower voltage value than the third control voltage, such that photo-carriers generated by the first absorption region, the second absorption region, and the third absorption region are collected by the first carrier-collection layer.

10. The optical sensing apparatus of claim 8, wherein, during an operation of the optical sensing apparatus, the first control voltage operates under an equal or higher voltage value than the second control voltage, and the second control voltage operates under a lower voltage value than the third control voltage, such that photo-carriers generated by the third absorption region are not collected by the first carrier-collection layer.

11. The optical sensing apparatus of claim 8, further comprising an interface dopant layer formed between the first absorption region and the second absorption region,
wherein, during an operation of the optical sensing apparatus, the second control voltage and the third control voltage are applied to create a carrier multiplication region in the first absorption region.

12. The optical sensing apparatus of claim 11, wherein the optical sensing apparatus is configured to operate under a Geiger mode.

13. An optical sensing apparatus comprising:
a plurality of sensing areas, each sensing area comprising:
a first absorption region configured to absorb light in at least a first spectrum with visible or near infrared wavelengths;
a second absorption region formed over the first absorption region, the second absorption region configured to absorb light in at least a second spectrum with near infrared or shortwave infrared wavelengths; and
a third absorption region formed over the second absorption region, the third absorption region configured to absorb light in at least a third spectrum with shortwave infrared or mid-wave infrared wavelengths.

14. The optical sensing apparatus of claim 13, further comprising a plurality of optical structures formed over the plurality of sensing areas.

15. The optical sensing apparatus of claim 14, wherein the plurality of optical structures comprise optical wavelength filters configured to pass multiple different wavelength ranges of light to respective sensing areas of the plurality of sensing areas.

16. The optical sensing apparatus of claim 15, further comprising readout circuitry configured to output electrical signals generated by absorbed optical signals.

17. The optical sensing apparatus of claim 16, further comprising processing circuitry configured to process the electrical signals to determine at least one of blood oxygen (biomolecule) information, alcohol (molecule) information, material information, glucose information, ambient light information, or proximity information associated with an object sensed by the optical sensing apparatus.

18. A method of forming an optical sensing apparatus, comprising:
forming a first absorption region configured to absorb light in at least a first spectrum with visible or near infrared wavelengths;
forming a second absorption region formed over the first absorption region, the second absorption region configured to absorb light in at least a second spectrum with near infrared or shortwave infrared wavelengths; and
forming a third absorption region formed over the second absorption region, the third absorption region configured to absorb light in at least a third spectrum with shortwave infrared or mid-wave infrared wavelengths.

19. An optical sensing apparatus comprising:
a n-doped silicon layer;
a silicon layer formed over the n-doped silicon layer;
a p-doped silicon layer formed over the silicon layer;
a first p-doped germanium layer formed over the p-doped silicon layer;
a superlattice structure formed over the p-doped germanium layer, the superlattice structure comprising multiple alternating Ge₁₋ₓSnₓ and Ge_{1-y}Si_{y} layers, where x and y is between 0 and 1; and
a second p-doped germanium layer formed over the superlattice structure.

20. The optical sensing apparatus of claim 19, further comprising:
a first buffer layer formed between the first p-doped germanium layer and the superlattice structure; and
a second buffer layer formed between the p-doped silicon layer and the first p-doped germanium layer.
